(19) United States
(12) Patent Application Publication
(10) Pub. No.: US 2008/0256406 A1
(43) Pub. Date: Oct. 16, 2008

(54) Testing System

(75) Inventor: Keith Arnold, Austin, TX (US)

Correspondence Address: FISH & RICHARDSON P.C., P.O BOX 1022, Minneapolis, MN, 55440-1022, US

(73) Assignee: PINTAIL TECHNOLOGIES, INC., Austin, TX (US)

(21) Appl. No.: 11/734,738

(22) Filed: Apr. 12, 2007

(51) Int. Cl. G01R 31/28

(52) U.S. Cl. 714/727

(57) ABSTRACT

There is provided an improved testing system. More specifically, in one embodiment, there is provided a method including accessing machine overall equipment effectiveness or efficiency (OEE) data including machine generated operational event states of an automated testing (ATE) system and times the machine generated operational event states occurred, receiving operator OEE data including operator entered operational event states of the ATE and times the operator observed operational event states, and combining the machine OEE data and the operator OEE data to generate merge OEE data.

The present invention relates in general to testing systems and, in particular, to systems and methods for improving the utilization of automated test (ATE) systems.

### BACKGROUND

An ATE system refers to a class of test equipment that generally includes automated delivery of components or subsystems to a test station. ATE systems are primarily employed to electrically test components from high volume manufacturing. Electrical testing is the identification and segregation of electrical failures from a population of devices (e.g., IC or wafers). An electrical failure is any IC that does not meet the electrical specifications defined for the device. In simplified terms, electrical testing consists of providing a series of electrical excitations or stimuli to the IC device under test (DUT) and measuring the response of the DUT. For every set of electrical stimuli, the measured response may be compared to an expected response, which is usually defined in terms of a lower and an upper limit. Any DUT that exhibits a response outside of the expected range of response may be considered a failure or, in some cases, a lower performing device.

In IC production mode, electrical testing is usually performed using an ATE system or platform, consisting of a tester and a handler. The tester performs the electrical testing itself, while the handler transfers the DUTs to the test site where they are positioned for proper testing, as well as reloading the DUTs back into a carrier after the testing process is completed.

The testing process executed by the ATE system is controlled by a test program or test software. The test program is usually written in a high level language and may consist of a series of several test blocks, each of which tests the DUT for a certain parameter. An exemplary test block sets up the DUT fixtures for proper testing of the DUT for a corresponding parameter. A test block may also tell the tester what electrical excitation needs to be applied to the DUT, as well as correct timing for the tests to be run.

A test program typically comprises two types of test blocks, parametric and functional. Functional testing checks if a device is able to perform its basic operation. Parametric testing checks if the device exhibits the correct voltage, current, or power characteristics, regardless of whether the unit is functional or not. A parametric test usually comprises forcing a constant voltage at a node and measuring the current response (force-voltage-measure-current, or FVMC) at that node, or forcing a constant current at a node and measuring the voltage response (force-current-measure-voltage, or FCMV).

Electrical testing is typically done at ambient temperature, but testing at other temperatures may also be done depending on the screening requirements. For instance, latch-up problems have better chances of being detected at an elevated temperature while hot carrier failures are more easily detected at low temperatures.

The handler in an ATE system delivers the DUT into a test station where probes are positioned to contact and supply stimuli. The positioning of the test probes and details for a particular stimulus are specified by the test program, which may run as an application on a computer operating system. The computer operating system may be configured to run any number of test programs or test interface programs as applications.

A test program that directs the operation of the ATE typically includes, “hooks” that allow the operational status of the ATE to be visible to other applications, also running in the background during test, that are designed to enhance the test program and the operation of the ATE. Such background applications may be configured to do a variety of tasks including, but not limited to, analyzing response data, generating input window directing operator input, determining trends in acquired data, etc.

ATE systems are expensive and their efficiency of utilization is important to overall product throughput, product cost, and more importantly, in quickly identifying any anomalies in the manufacturing or test process that may be corrected before more failed or out-of-specification DUTs are manufactured or improperly categorized.

An ATE operator is usually assigned one or more ATEs with the task of assuring that the utilization of each is maximized. To aid the operator (or other support personnel), a web-based interface tool that is accessed from the ATE console may provide the operator or maintenance technician an input window wherein the operator can input data, such as for example, machine state codes or ATE set-up configuration data. The machine state codes are configured to enable the status of the ATE as “seen” by the operator or technician to be inputted and recorded as a function of time (e.g., time stamped when entered). This operator entered machine state code data, referred to as operator overall equipment effectiveness or efficiency (OEE) data, may be used in calculations to determine OEE for a particular ATE. However, the value of this operator OEE data is highly dependent on the user, thus procedures and training are required along with operator discipline to yield good operator OEE data. Such procedures may include establishing a master set of machine state codes, general rules for what machine state codes are used in what particular situations, setting consistently using the machine state codes across all manufacturing floors, shifts, and tester groups, and establishing procedures for who may enter machine state code data and set-up data. ATE operator entries in the above-described interface tool may not always be accurate.

A software monitor running on the ATE, on the other hand, is a very accurate data source for determining the timing of ATE events and thus may be the source of machine generated OEE data (machine OEE data). The software monitor may use DUT lot classification and DUT lot data to derive many reportable ATE machine states. The software monitor may detect and report idle periods within a DUT lot and may be configured to be self-reporting and fully automated. These features produce insights while DUT lots are being tested (data is available) but may not provide any insight into machine states between DUT lots or at times when the machine is not providing any applicable data.

### SUMMARY

There is provided an improved testing system. More specifically, in one embodiment, there is provided a method including accessing machine overall equipment effectiveness or efficiency (OEE) data including machine generated operational event states of an automated testing (ATE) system and times the machine generated operational event states occurred, receiving operator OEE data including operator entered operational event states of the ATE and times the operator observed operational event states, and combining the machine OEE data and the operator OEE data to generate merge OEE data.

In another aspect, there is provided a physical computer-readable storage medium embedded with instructions that operate in a computer environment to store a first data stream containing machine generated data associated with a semiconductor tool, to store a second data stream containing operator generated data associated with the semiconductor tool, and to generate a third data stream containing an evaluative merging of the first and second data streams.

### BRIEF DESCRIPTION OF THE DRAWINGS

FIG. 1 is a block diagram the ATE and various software applications that run under the operations system of the ATE in one embodiment;

FIG. 2 illustrates as a function of time, operator OEE data, machine OEE data and merge OEE data generated according to one embodiment;

FIG. 3 is a flow diagram of a method used in one embodiment;

FIG. 4 is a flow diagram of an exemplary rule based algorithm suitable for generating merge OEE data according to one embodiment; and

FIG. 5 is a diagram of an OEE of the ATE calculated using operator OEE data, machine OEE data, and merge OEE data according to one embodiment.

### DETAILED DESCRIPTION

In the following description, numerous specific details are set forth. However, those skilled in the art may practice present invention without such specific details. In other instances, well-known circuits may be shown in block diagram form in order not to obscure them with unnecessary detail. For the most part, details concerning timing and the like may have been omitted in as much as such details are not necessary to obtain a complete understanding and are within the skills of persons of ordinary skill in the relevant art.

Refer now to the drawings wherein depicted elements are not necessarily shown to scale and wherein like or similar elements are designated by the same reference numeral through the several views.

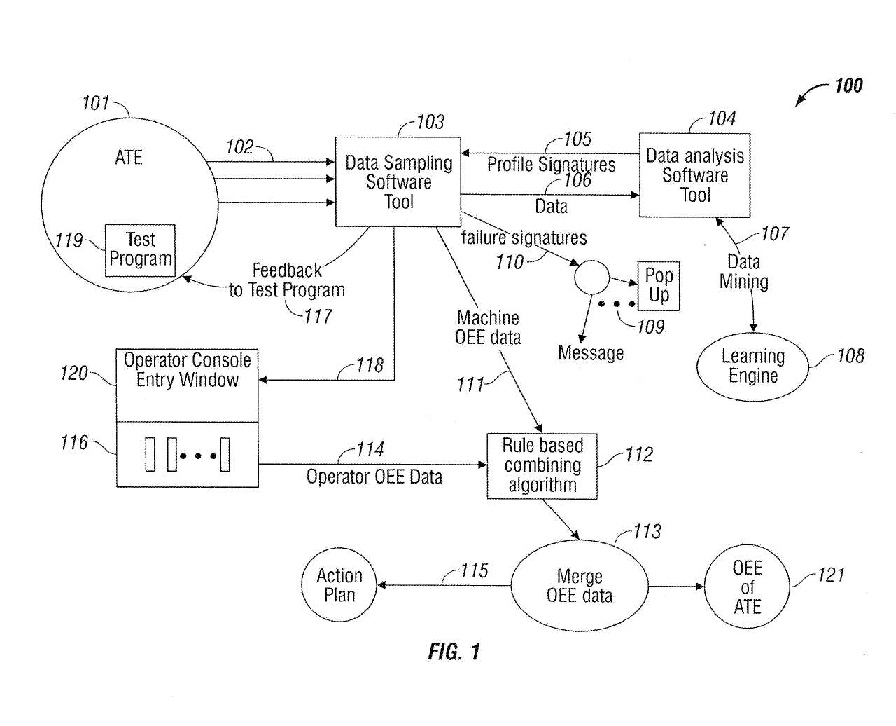

FIG. 1 is a block diagram of an exemplar ATE system 100 including various software applications shown in block diagram form as interacting with ATE data and generating data or an interface window on a console. ATE 101 comprises elements necessary to automate a test process: for example, a device handler, a probing station, and a computer with an operating system configured to run various applications. A particular data sampling software tool 103 receives real time measurement data of parameters 102 generated in response to control data from a test program 119. Data sampling software tool 103 may provide real time statistical analysis of the parameter test data as well as receiving data defining machine event states of the ATE 101. In one embodiment, data sampling software tool 103 configures time sequential machine OEE data 111. Data sampling software tool 103 may also generate an operator interface window 120 displayed on the console of the ATE 101 that allows the operator to enter his determination as to the machine event state of the ATE 101. Data sampling software tool 103 may define a set of controlled input options 116 that the operator may choose from when entering his determination of machine event states through interface window 120. The operator inputs are time stamped and become time sequential operator OEE data 114.

The machine OEE data 111 is time accurate as it is automatically acquired. However, from time to time, machine OEE data 111 may lack information, especially at times when the ATE 101 is in a machine event state that does not produce data; for example when the ATE 101 is in a Down state. On the other hand, the operator OEE data 114, while time stamped, is dependent on an operator or some support personnel being present to make an entry that indicates the machine event state of the ATE 101. Even though the time accuracy maybe less than desired, the operator is able to make visual observations and/or off-line measurements, and thus provide information rich inputs as to the machine state of the ATE 101.

In a one embodiment, a rule based algorithm 112 is used to combine the operator OEE data 114 and the machine OEE data 11 to generate merge OEE data 113 that incorporates characteristics not available in each data stream alone. The merge OEE data 113 may be processed to produce one or more action plans that effect changes that enable better utilization of the ATE 101. For example, the merge OEE data 114 may be employed to calculate an OEE 121 of the ATE that better represents the actual utilization of the ATE 101.

The ATE system 100 includes a data analysis software tool 104 that receives data 106 from data sampling software tool 103 and stores historical data. This historical data may be analyzed to determine trends and generate profile signatures 105 that indicate failure modes in particular devices tested by ATE 101, For example, learning engine 108 may use data mining algorithms 107 to search the historical data in tool 104 to determine profile signatures 105 that are fed back to data sampling software tool 103. When data sampling software tool 103 acquires data 102 that matches a profile signature 105 it may generate failure signatures 110 that may trigger the generation of outputs 109, such as, for example, a message or a particular type of “pop-up” visible to an operator or other support personnel either locally or remotely.

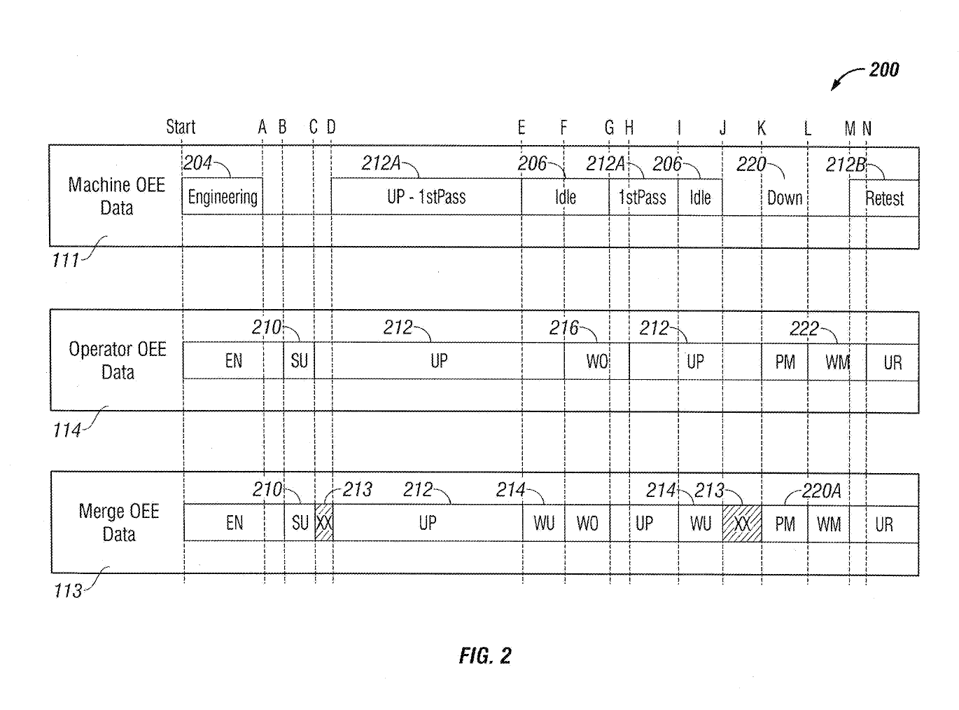

FIG. 2 illustrates a comparison of exemplary machine OEE data 111, operator OEE data 114 and merge OEE data 113 generated according to various embodiments such as, for example, the test process described with regard to FIG. 1. Machine OEE data 111 is a data stream generated automatically by an application program (e.g., tool 103 or tool 104 in FIG. 1) and has machine event states defined by times A, D, E, G, I, J, and M. Likewise, operator OEE data 114 is a data stream entered by an operator and has machine event states defined by times B, C, F, H, K, L, and N. In this example, machine OEE data 111 defines the time interval Start-A as the ATE Engineering (EN) state 204. During the interval A-D, the machine OEE data 111 has no indication of the machine event state of the ATE 101. The operator OEE data 114 indicates that during the overlapping time period A-B, ATE 101 is actually still in EN state 204. Since the Data sampling software tool 103 has no data during this period, an exemplary rule defers to the operator OEE data 114 and generates, in the interval A-B, merge OEE data 113 that coincides with the operator OEE data 114 in the same interval A-B.

At time B, the operator OEE data 114 indicates that ATE 101 has changed to the Set-Up (SU) state 2101. The machine OEE data 111 still does not indicate any particular state (no data) and an exemplary rule defers to the operator OEE data 114 and merge OEE data 113 is updated to indicate SU state for 210 the time interval B-C.

At time C, operator OEE data 114 indicates that the operator inputted an UP event state 212 for ATE 101. However, machine OEE data 111 which automatically indicates the UP state 212 once testing has actually begun, does not agree with the operator OEE state at time C. Rather, machine OEE data 111 indicates nothing until a 1^{st} pass lot processing starts at time D. 1^{st} pass processing may, in some embodiments, be considered a sub-set of the UP state 212. In the interval C-D, therefore, machine OEE data 111 and operator OEE data 114 do not match. In this case, an exemplary rule defers to machine OEE data 111 and merge OEE data 113 is updated to indicate an unknown machine state 213 (XX) in the time interval C-D.

During the interval D-E, the operator OEE data 114 and machine OEE data 111 both indicate that ATE 101 is in UP event state 212A (a first pass test of a lot is in process.) At time E, the machine OEE data 111 indicates ATE 101 transitioned to an Idle event state 206 in the interval F-G. Operator OEE data 114 indicates that for some reason, the operator failed to input Idle event state 206 beginning at time E. There can be many reasons for such imprecision such as, for example, the operator may be at another ATE and failed to note the event state transition. In this case, an exemplary rule defers to the machine OEE data 111 and the merge OEE data 113 is updated to indicate a Wait Unknown (WU) event state 214 (the ATE is idle with no further explanation available).

At time F, the operator enters a Waiting for Operator (WO) machine event state 216 while the machine OEE data 111 indicates that ATE 101 is still in Idle state 206. In this case, an exemplary rule again defers to the operator OEE data 114 as the operator has provided additional detail. At time G, the machine OEE data 111 indicates that the first pass processing 212A has resumed while the operator OEE data 114 continues to indicate WO machine event state 216. In this case, the exemplary rule defers to the machine OEE data 11 as being the best indicator of the machine event state of ATE 101. Merge OEE data 113 is updated to indicate that ATE 101 is in UP state 212 (testing devices).

At time I, the operator again failed to indicate that ATE 101 went into the Idle state 206. The exemplary rule defers to the machine OEE data 111 and updates merge OEE data 113 to indicate a WU event state 214. At time J, the machine OEE data 111 indicates the end of Idle state 206 and the entry into the Down state 218 for the interval J-K. During the interval J-K, while the operator OEE data still indicates the UP state, the machine OEE data 111 is a better indicator that the machine is actually in a Down state (no data) 220. Because there are many reasons why an ATE maybe down, the merge OEE data indicates unknown state XX 212. At time K, the operator adds more detail and indicates that ATE 101 is actually in the preventative maintenance (PM) state 220A while it is Down. Since this adds additional informational detail, merge OEE data 113 is updated to coincide with the operator OEE data 114.

At time L, the machine OEE data 11 still indicates that ATE 101 is in the Down state 220 while the operator inputs that the machine event state is in a Waiting for Material (WM) event state 222. Again, the operator OEE data 114 adds additional informational detail and merge OEE data 113 is updated to coincide with the operator OEE data 114. At time M, the machine OEE data 111 indicates that ATE 101 has transitioned to the UP Retest (UR) event state 212B. In this example, the operator did not input the start of Retest until time N and thus the exemplary rule defers to the machine OEE data 111 as being more accurate and updates the merge OEE data 113 to coincide with the machine OEE data 111 during the period from time N until the end of the monitored ATE 101 time period 200.

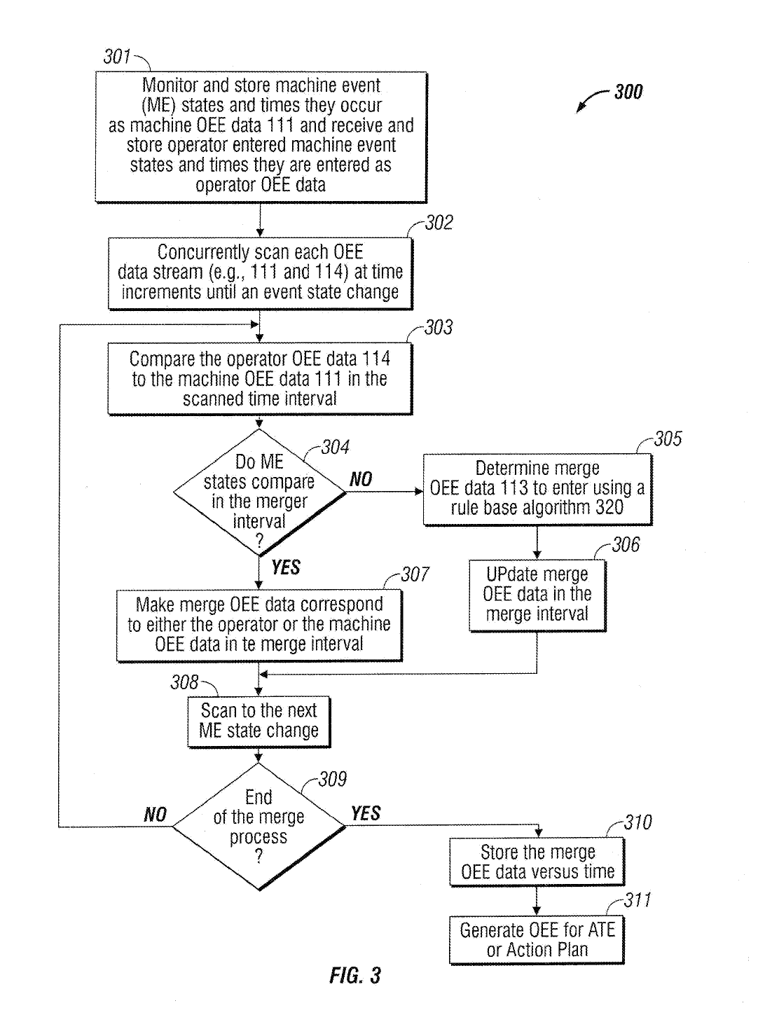

FIG. 3 is a flow diagram 300 of steps used in one embodiment. In step 301, ATE machine event states and the times they occur are monitored and stored as machine OEE data 111. Likewise in step 301, operator entered machine event states and the times they were entered are stored as operator OEE data 114. In step 302, the machine OEE data (e.g., 111 in FIG. 2) and operator OEE data (e.g., 114 in FIG. 2) are scanned concurrently. In step 303, the operator OEE data 114 is compared with the machine OEE data 111 in an interval to determine a machine event state to record in the corresponding time interval as merge OEE data 113. In step 304, a test is done to determine if the operator OEE data 114 and the machine OEE data 111 correlate in the interval. If the result of the test in step 304 is NO, then a branch is taken to step 305 where a rule based algorithm 320 is used to determine what merge machine event state is most appropriate to enter as the merge OEE data 113 for the time interval of interest. In step 306, the merge OEE data 113 is updated to reflect a merge machine event state determined by algorithm 320. A branch is then taken to step 308.

In step 308, the operator OEE data 114 and the machine OEE data 111 are scanned until a next machine event state change. In step 309, a test is done to determine if the end of the ATE test interval has been reached. If the end of the ATE test interval has been reached, then in step 310 the merge OEE data 113 is stored for further analysis to generate one or more action plans or to calculate a utilization metric or the OEE of the ATE according to the merge OEE data 113. If the merge process has not ended, a branch is taken back to step 303.

If the result of the test in step 304 is YES, meaning that the operator and machine assessments of the ATE machine state agree, then the merge OEE data 113 is updated to correspond in step 307. Again steps 308 and 309 are executed resulting in a branch back to step 303 or to step 310 as previously described.

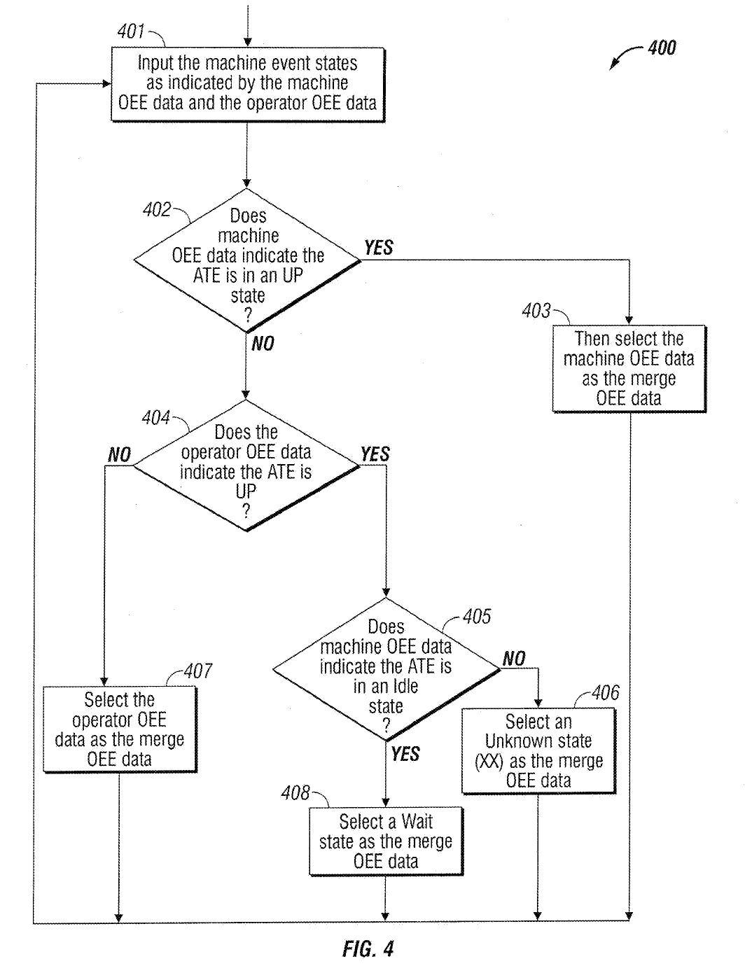

FIG. 4 is an exemplary decision making flow diagram 400 that is suitable for implementing a process for combining machine OEE data and operator OEE data to generate merge OEE data according to one embodiment. The miles in this flow diagram may be implemented using a look-up table algorithm or by using another decision making process coded in a set of instructions such as, for example, by a state machine logic. This example shows a particular set of machine event states and other miles may be used to determine how to combine machine OEE data 111 and operator OEE data 114 to generate merge OEE data 113.

The combining process starts in step 401 by inputting the machine event states as indicated by the operator (operator OEE data 114) and the data received by a monitor application (machine OEE data 111). In step 402, a test is done to determine if the machine OEE data 111 indicates that ATE 101 is in the UP machine event state 212. If the result of the test in step 402 is YES, then in step 403 the merge OEE data 113 is updated to machine OEE data 111 to indicate the machine event state of ATE 101. A branch is then taken back to step 401 to read in new OEE data which may include both machine OEE data 111 and operator OEE data 114. If the result of the test in step 402 is NO, then in step 404 a determination is made as to whether operator OEE data 114 indicates that ATE 101 is in UP state 112. If the result of the test in step 404 is YES, then in step 405, a determination is made as to whether the machine OEE data 111 indicates that ATE 101 is in Idle state 206. If the result of the test in step 405 is NO, then further details of the DOWN state 220 of ATE 101 are not known and the merge OEE data 113 is updated to indicate an Unknown event state XX 213 (step 406). If the result of the test in step 405 is YES, then the rule selects a Wait state as the merge OEE data 113 in step 408. Then a branch is taken back to step 401. If the result of the test in step 404 is NO, then the operator OEE data 114 is selected as the merge OEE data 113 in step 407 and a branch is then taken back to step 401.

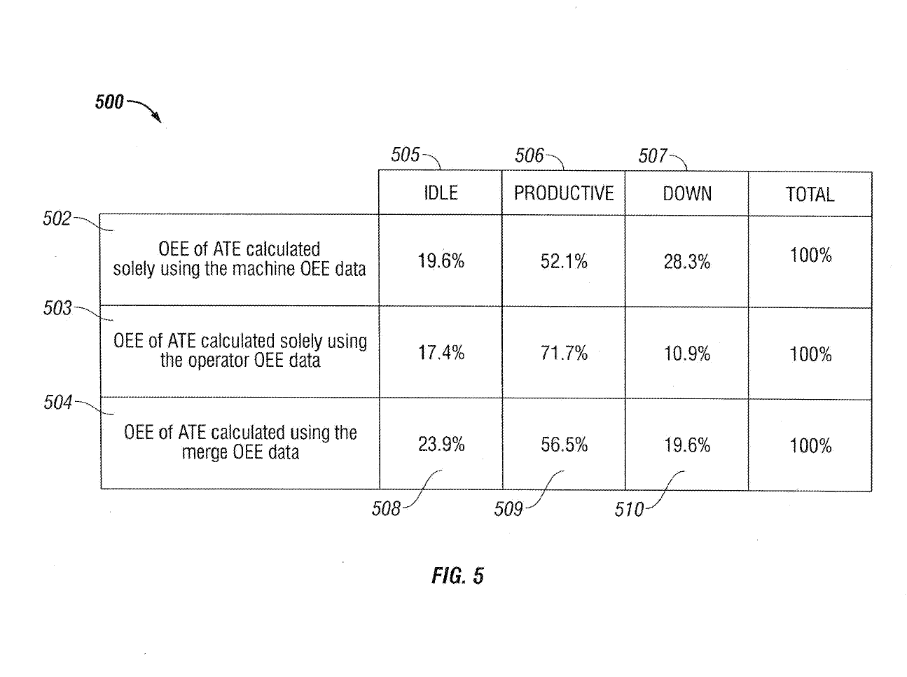

FIG. 5 is an exemplary table showing a process 500 for determining differences in the OEE of the ATE when calculated using the operator OEE data in process 503, when calculated using machine OEE data in process 502, and when calculated using merge OEE data in process 504 according to one embodiment. Headings 505-507 indicate exemplar machine states categorized as either IDLE 505, PRODUCTIVE 506, or DOWN 507. The merge OEE data 113 indicates that ATE 101 is in IDLE state 505 longer than indicated by either machine OEE data 113 or the operator OEE data 114. However, merge OEE data 504 shows that the ATE has greater PRODUCTIVE time 506 than indicated by the machine OEE data but less than indicated by the operator OEE data. Likewise, the DOWN time 510 indicated by the merge OEE data is greater than indicated by the operator OEE data but less than the indicated by the machine OEE data.

Analyzing the results as shown in FIG. 5 enables action plans that are properly focused. For example, the operator may need more options in entering operator OEE data at ATE console 120. The operator may have too many machines to cover and thus does not update the operator OEE data as frequently as necessary to accurately indicate actual productive time. As such, maintenance plans can be updated, engineering efforts can be directed to particular elements of the ATE that fail too often, etc.

The following is a more detailed description of particular application software that is used by some embodiments. This description provides additional detail and the particular application software are given identifying names such as “TestScape”, “SwifTest” and “StatusTool” which identify particular offerings of the present Assignee.

TestScape is an exemplary software application that provides a comprehensive OEE solution for the active management of tester assets. The presentation layer of a TestScape application may change from user to user and may be dependent on particular needs and desires of the manufacturing operation. StatusTool is an exemplary on-tester software that the operator and other test floor personnel use to enter system state, configuration, and other pertinent information in real time. SwifTest is an exemplary application program that derives lot summary data and mid-lot data from the standard test data format (STDF) file or data conduit and sends this data to the TestScape application. From this data, exemplary application TestScape determines certain machine states, yield and throughput information. TestScape may also contain various maintenance tables and screens for master data that may be used in conjunction with the above data streams describing machine event states.

The input of machine event states may be considered to come from all of the exemplary application program sources described: StatusTool, SwifTest, and TestScape master data tables. Combined, these sources provide an accurate, real-time assessment of ATE event activity. Each of these application sources are described in greater detail in the following descriptions.

In various embodiments, OEE information may be directed to three destinations: TestScape generated Web Pages, data exports to Excel® and PDF® files, and an operator feedback console (OFC) generated by the StatusTool application. TestScape Web Pages may include various charts, tables, and graphs as later described. Data export to an Excel® program allows recreation of the OEE calculations and other data that may be pertinent. Full web page export to PDF® files may include the selection criteria and any other data constraints.

The exemplary StatusTool application may display productivity and yield information that are fed back to the operator via the StatusTool OFC to create a fill loop system for real time improvement.

Industry specifications SEMI 10 specification and SEMI E79, define machine state codes and productivity equations and are the foundation of all OEE calculations described and used in various embodiments. OEE codes, including customer specific codes, map to the SEMI E10 codes. Typically, the lowest level of OEE measurement is a Test Cell, which is defined as one test head on a tester. Most testers are single head, each of which has independent OEE data and measurement metrics.

The following are a set of terms that may be used in conjunction with embodiments described herein:
1. OEE is defined as the Overall Equipment Efficiency (Effectiveness).
2. AE is the Availability Efficiency defined as the fraction of time that the equipment is in a condition to perform its intended function. This may also be referred to as Total Utilization.
3. PE is the Performance Efficiency defined as the fraction of uptime that the equipment is processing actual units (total insertions) at theoretical efficient rates.
4. QE is the Quality Efficiency defined as the ratio of theoretical production time for effective units (total passing units) to the theoretical production time for actual units (total insertions).
5. OE is the Operation Efficiency defined as the fraction of equipment uptime that the equipment is processing actual units. This may also be referred to as Operational Utilization.
6. RE is the Rate Efficiency defined as the fraction of production time that the equipment is processing actual units at theoretically efficient rates.
7. Theoretical Units Per Hour (TUPH) is defined as the theoretical unit rate per hour (assuming 100% yield and no processing inefficiencies, including time to load and unload parts)
8. Actual Units Per Hour (AUPH) is the defined as the actual number of devices tested divided by the total production time (start of lot to end of lot, inclusive of any inefficiency).

The following formulas may be used to calculate certain metrics used according to a one embodiment:

OEE=AE*PE*QE (1)

Where:

AE=(Up Time)/(Total Time) (2)

PE=OE*RE (3)

QE=(Theoretical Production Time for Effective Units)/(Theoretical Production Time for Actual Units) (4)

OE=(Production Time)/(Up Time) (5)

RE=(Theoretical Production Time for Actual Units)/(Production Time) (6)

Theoretical Production Time for Actual Units=Actual Units/TUPH (7)

Theoretical Production Time for Effective Units=Effective Units/TUPH (8)

It may be concluded from the above formulas that:

QE=(Total Passing Devices)/(Total Device Insertions) (9)

RE=(Total Device Insertions)/(TUPH*Production Time)=AUPH/TUPH. (10)

The following Table 1.0 lists correspondences between OEE codes and states and their descriptions, used in a one embodiment, and the previously referred to industry standard E10 states. In one embodiment, each unique machine state of the equipment is designated by an OEE code. Each of these OEE codes are then grouped under the major blocks (E10 states).

TABLE 1.0
E10 and OEE States

| | OEE Sub | |
|---|---|---|
| E10 State | State | Description |
| Productive | UP | up and running regular production devices |
| | Retest | up and running retest or re-screen devices |
| | Quality | running quality samples, AOQL, qualification material |
| | UpEng | up and running engineering production |
| | UpEngExt | up and running external engineering production |
| | Unknown | up and running product of unknown type |
| Engineering | Eng | engineering development, experiments, software |
| | | qualification |
| | EngExt | external engineering development |
| Standby | Idle | up and loaded but system is waiting for some action to |
| | | resume, intra-lot idle time |
| | NoOp | ready to run but waiting for an operator |
| | NoMatl | ready to run but waiting for production material |
| | NoEquip | ready to run but waiting for equipment, handler, DIB . . . |
| | Standby | ready to run but waiting for some unknown reason |
| Unscheduled Down | Down | system is down for unknown reason |
| | Repair | unscheduled repairs and maintenance |
| Scheduled Down | Setup | setup of a tester in preparation for running production |
| | PM | scheduled periodic maintenance |
| Non Scheduled | NST | default state in the absence of any other information |

The E10 states are an industry standard and are not changed. However, the OEE sub-states may be changed and expanded per individual user needs. The exemplary application TestScape is initially installed with a default set of OEE codes for example, the ones as shown above in Table 1.0. The Non-Scheduled state (NST) shown is the default state if no other input is available and is not changed or removed.

The following is a description of how exemplary application programs collect and process data used in some embodiments.

The exemplary StatusTool application has the primary interface for the operator and other test floor personnel. Data is intended to be entered in real time. The StatusTool application has three sections: OEE input, Setup, and Feedback. In one embodiment the StatusTool is a Web based application that is configured to run on a broad array of Internet browser platforms that match those present on most test floors. The exemplary StatusTool may incorporates language aliasing to allow the operator to view the page in their native language in those cases where the manufacturing floor may be remote from engineering facilities or other support locations.

An exemplary OEE Tab provides a selection of E10 states from which an operator may choose. Colors may be used and would follow the E10 code colors from a OEE master table. The top of the tab may have a section to prompt the operator for their identification (ID). The bottom of the OEE Tab may have a place for operator comments. When the operator enters operator OEE data into the OEE Tab or changes states, then a record is sent to TestScape with the data, tester node and timestamp.

Setup Tab enables the operator or setup technician to enter key configuration data. The values for the configuration data normally come from a configuration lookup table for example from the exemplary application TestScape. The operators are trained to use intelligence to reduce operator input requirements. For example, if an exemplary “Product XYZ” only uses one type of handler and one type temperature, then a default to that setting should be incorporated. In the event the master lookup table is not being maintained, the operator is allowed to designate ‘other’ or possibly allowed a free entry. Where ever possible, the operator is provided with a drop-down list and discouraged from providing self-scripted entries. To further improve the integrity of the operator OEE data, the operator should provide an indication to acknowledge operator OEE data entry. A record of the operator entry is then sent to exemplary application TestScape with operator OEE data, tester node, and timestamp.

The following are exemplary input fields for entry of operator OEE data used in accordance with embodiments described herein.
1) Product is a primary field implemented as drop-down that is required and may have sub select products based on tester type being reported.
2) Handler Type is a field in a drop-down list.
3) Handler ID is a field in a drop-down list with sub select from handler type.
4) DIB ID is a required field in a drop-down list with sub select from product type.
5) Contactor is a field in a dropdown list
6) Temperature is a required field in a drop down list from lookup of product.
7) Setup Comment is 256 character field.

The exemplary OFC attaches to the bottom of the StatusTool and may be used to provide graphical feedback data such as:
1) a background color that indicates the overall state of a metric
2) a yield band that represents the historical first pass+/− one sigma
3) factory target and maximum threshold
4) OEE band as a factory target
5) mid-lot updates and start of a lot

The exemplary SwifTest application program is configured to provide machine event status data and mid-lot updates to exemplary program TestScape. In one embodiment the exemplary TestScape program may infer the E10 states and from the reported machine OEE states from the lot class field using a lookup table. For example:

| Machine OEE data | E10 machine states |
|---|---|
| 1st Pass testing | Productive - UP |
| Retest | Productive - Retest |
| Correlation | Scheduled Down - Setup |
| Engineering | Engineering - Eng |
| QA | Productive - Quality |
| Other | Productive - Unknown |
| No lot data | NST |
| Idle | Idle productive code (e.g., UI) |

During the processing of a lot, Idle events may occur. These Idle events override the Lot class derived state and may be designated as an Idle productive code such as UI.

When implementing some embodiments, other issues may need consideration. For example, the following is some data integrity considerations.
1. Lot Time over lap, which is due to differences in tester time standards, the loader should validate the tester ID and validate “Lot stop time” by comparing to last Idle machine event.
2. No Lot end time requires the loader to derive “Lot stop time” from other Lot information data using an exemplary order of priority as follows:
   a) Use timestamp of load time into the exemplary TestScape database
   b) Use timestamp of last Idle machine event
   c) Use timestamp of last mid-lot update from same lot
   d) Synthesize the lot stop time as the start time+(total devices tested/target UP hours ((TargetUPH)), adjusted for number of sites reported. The synthesized lot stop time should not be greater than the lot start time of the next lot.
3. Any changes to the data may be noted in a “Data integrity” field so that such changes may be traced and used in the formulation of data integrity metrics if necessary.

A key component of the OEE metric is rate efficiency. In order for rate efficiency to calculate properly, a theoretical UPH number is needed. This number may vary from product to product and test program to test program as the test time is for each may be different. There are four possible sources for this critical information:
1) A static lookup value based on the product or test program. A product master table in the exemplary TestScape application may contain a Theoretical UPH value for each product. Normally there will be a large number of products and the constantly changing nature of this data makes it likely that this data will not be properly maintained resulting in erroneous rate efficiency metrics.
   TUPH=Theoretical UPH lookup
2) A static ratio based on the actual UPH measured. This value might be 1.2 times the actual UPH measured and may be used when no other data is available.
   TUPH=1.2*Actual UPH
3) Modeled Theoretical UPH may be possible where the test time, index time and number of test sites are known. This method is popular but also suffers from poor data maintenance as the test programs are changed frequently.
   TUPH=optimal number of test sites(MaxSites)*3600/(test time in seconds+index time in seconds)

When model parameters are entered into the product master screen, the Theoretical UPH value is calculated and entered into the TUPH field.
4) Periodically calculate a Theoretical UPH that is derived from empirical data within the exemplary TestScape application. This method has the advantage that no data maintenance is required and may track the actual Theoretical UPH better than other methods. The algorithm for calculating Theoretical UPH is as follows:
   a) Select all lots from the last 90 days (configurable) where the yield is greater than the low yield limit and the quantity is greater than x (example, 250 pieces).
   b) Since some products are tested using 1 site, 2 sites, 3 sites, etc., identify the maximum number of sites that each product and test program uses. This is the optimal site configuration for a theoretical UPH calculation, denoted as MaxSites.
   c) To calculate the highest achievable UPH take the lots found in ‘a’ that where processed with a site count of MaxSites. From these lots calculate the process time from start to end of the lot TotalTime and subtract the total intra-lot idle time TotalIdleTime to get the actual running time for processing the lot Running Time.

d) Theoretical UPH assumes all devices are passing but there will always be some failing devices in the exemplar empirical data set. Failing devices take less time to test than passing devices and too many failing devices could skew the result. Adjust accordingly. Consider that processing time in a quad site scenario shortened only if all 4 devices fail. If even 1 device passes, then the test time will be maximized for all. If a device yields 90% and is being tested with 4 sites in parallel, then the probability that all 4 devices fails at the same time is (0.1)⁴, which is 0.0001 or 0.01%. Even though the failing time contribution is extremely small, multiply these few instances by some arbitrary factor to estimate the test time if they had passed. Extending this method to the generalized case yields:

$$TUPH = * [ 1 - ( 1 - B ) * Pf ] \frac{Total Units}{RunningTime} \qquad ( 11 )$$

Where:
Pf=(1−Yield)
B=ratio of failing device test time to passing device test time (Values usually range from 0.5 to 0.7)
Total Units=total of all passing and failing devices tested
Running Time=(Lot Stop Time−Lot Start Time)−ΣIdle Event Time

The above empirically calculated TUPH may be recalculated, for example, once a day and the product master may then be updated with the newly calculated value.

The exemplary TestScape determines the Theoretical UPH (TUPH) as follows:
1. If the product master contains a static TUPH entry and the Use Calculated TUPH flag is false and the static TUPH value is greater than zero, employee TestScape the static TUPH from the product master.
2. Else, if the product master contains an empirically calculated TUPH entry greater than zero and the Use Calculated TUPH flag is true, TestScape uses the calculated TUPH from the product master.
3. Else, TestScape uses a static ratio to determine the TUPH by multiplying Actual UPH times 1.2.

The exemplary TestScape program receives machine OEE data and operator OEE data streams from the exemplary SwifTest application and exemplary StatusTool application, respectively, and generates merge OEE data 113 using a rule based algorithm according to a one embodiment.

Exemplar SwifTest is an example of the earlier described application for data sampling software tool 103 and, as such, generates machine OEE data 111. It employs derived E10 codes and thus only considers states Production, Engineering, and Setup all of which are part of UP Time. The void of data between lots is non-productive and hence may be assumed to be either Down Time or Non Scheduled Time. Even though these machine OEE data (E10 states) do not represent the full OEE picture, they are sufficient to calculate the core OEE metrics and are accurate in the time domain. One area of possible error is the accurate determination of Standby states. Intra-lot idle time may be used to determine a portion of the Standby time but inter-lot standby events are not known.

The three components of the OEE previously described may be alternatively expressed as:

AE=(Up Time)/(Total Time) (12)

PE=OE×RE=(Total Passing Devices)/(TUPH×Up Time) (13)

QE=(Total Passing Devices)/(Total Device Insertions) (14)

Note that these equations use Up Time, Total Time, TUPH, and device counts. All these parameters may be extracted from the SwifTest OEE data stream. In the absence of any StatusTool operator OEE data, Swiftest derived E10 codes are used. This can be helpful in the early stages of implementation when StatusTool operator OEE data may only be available in limited amounts.

StatusTool operator OEE data contains an array of codes inputted directly by the operator. Operator OEE data 114 may not always contain an accurate depiction of ATE machine states or the time they were entered. The accuracy of operator OEE data 114 is directly dependent on the training and discipline of operator. However, the StatusTool operator OEE data is useful when a user desires a more detailed picture of ATE 101 utilization. Operator OEE data 114 from StatusTool allows more detailed description of the ATE machine states as the operator has visibility to information when none is available from the machine OEE data 111. This gives a user a better understanding of where ATE time is really being spent.

At times, machine OEE data 111 and operator OEE data 114 will augment each other, at other times, one will augment the other, and at other times, the two data streams will be in direct conflict. A rules based algorithm that may be utilized to properly deal with the above three scenarios, may be implemented using, for example, a state lookup table. The following Table 2.0 is an exemplary illustration of generating merge OEE data 113 by combining operator OEE data 114 and machine OEE data 111.

TABLE 2.0
Merge Lookup

| SwifTest Lot | | StatusTool | Merge E10 | |
|---|---|---|---|---|
| Class | StatusTool E10 State | OEE code | State | Merge OEE Code |
| First Pass | Non-Scheduled Time | | Productive | UP |
| (FP) | Unscheduled Down | | Productive | UP |
| | Scheduled Down | | Productive | UP |
| | Engineering | | Productive | UP |
| | Standby | | Productive | UP |
| | Productive | | Productive | UP |
| | null | | Productive | UP |
| Retest (RT) | Non-Scheduled Time | | Productive | Retest |
| | Unscheduled Down | | Productive | Retest |
| | Scheduled Down | | Productive | Retest |
| | Engineering | | Productive | Retest |
| | Standby | | Productive | Retest |
| | Productive | | Productive | Retest |
| | null | | Productive | Retest |
| QA | Non-Scheduled Time | | Productive | Quality |
| | Unscheduled Down | | Productive | Quality |
| | Scheduled Down | | Productive | Quality |
| | Engineering | | Productive | Quality |
| | Standby | | Productive | Quality |
| | Productive | | Productive | Quality |
| | null | | Productive | Quality |
| Engineering | Non-Scheduled Time | | Engineering | Eng |
| | Unscheduled Down | * | Unsch Down | * |
| | Scheduled Down | * | Sched Down | * |
| | Engineering | | Engineering | Eng |
| | Standby | | Engineering | Eng |
| | Productive | | Engineering | Eng |
| | null | | Engineering | Eng |
| Correlation | Non-Scheduled Time | | Unsch Down | Down |
| | Unscheduled Down | | Unsch Down | Down |
| | Scheduled Down | | Sched Down | Setup |
| | Engineering | | Engineering | Eng |
| | Standby | * | Standby | * |
| | Productive | | Sched Down | Setup |
| | null | | Sched Down | Setup |
| Unknown | Non-Scheduled Time | | NonScheduled | NST |
| | Unscheduled Down | * | Unsch Down | * |
| | Scheduled Down | * | Sched Down | * |
| | Engineering | * | Engineering | * |
| | Standby | * | Standby | * |
| | Productive | * | Productive | * |
| | null | | Productive | Unknown |
| null | Non-Scheduled Time | * | NonScheduled | * |
| | Unscheduled Down | * | Unsch Down | * |
| | Scheduled Down | * | Sched Down | * |
| | Engineering | * | Engineering | * |
| | Standby | * | Standby | * |
| | Productive | * | Productive | UP |
| | null | | NonScheduled | NST |
| FP + IDLE or | Non-Scheduled Time | | Standby | Idle |
| RT + IDLE or | Unscheduled Down | | Standby | Idle |
| QA + IDLE | Scheduled Down | | Standby | Idle |
| | Engineering | | Standby | Idle |
| | Standby | * | Standby | * |
| | Productive | | Standby | Idle |
| | null | | Standby | Idle |

The cells with “*” mean that the OEE codes received from StatusTool should be used in the merged result without alteration. When a new tester is added to the system, the initial state of this system will be set to Non-Scheduled Time.

With the StatusTool OEE states and SwifTest lot data meaningful OEE metrics can be created that indicate the utilization of ATE production equipment. In accordance with SEMI standard E79, TestScape can calculate the OEE metric and its components metrics: Availability Efficiency, Rate Efficiency, Operational Efficiency and Quality Efficiency as described above. In addition to these basic metrics, a user may create other useful metrics such as:

First Pass Efficiency=First Pass Test Time/Productive Time (15)

Retest Efficiency=Retest Time/Productive Time (16)

Equipment Utilization=(Productive Time/Total Time)×(Actual UPH/Theoretical UPH) (17)

Mean Time between Failures (MTBF)=productive time/number of Unscheduled Repair events during productive time. (18)

Mean Time to Repair (MTTR)=total time of Unscheduled Repair/number of Unscheduled Repair events. (19)

Mean Cycles between Failures (MCBF)=total lots tester/number of Unscheduled Repair events. (20)

Mean Time Offline (MTOL)=total down time/number of down time events. (21)

Although the numerous embodiments have been described in detail, it will be apparent that those skilled in the art may be embodied in a variety of specific forms and that various changes, substitutions and alterations can be made without departing from the spirit and scope of the invention. The described embodiments are only illustrative and not restrictive and the scope of the invention is, therefore, indicated by the following claims.

What is claimed is:

1. A comprising:
accessing machine OEE data including machine generated operational event states of an ATE and times the machine generated operational event states occurred;
receiving operator OEE data including operator entered operational event states of the ATE and times the operator observed operational event states; and
combining the machine OEE data aid the operator OEE data to generate merge OEE data.

2. The method of claim 1 wherein the merge OEE data provides detail of operational event states of the ATE not available separately in either the machine OEE data or the operator OEE data.

3. The method of claim 1, comprising using the merge OEE data to calculate an OEE of the ATE as a percentages of total time the ATE is in an UP event state.

4. The method of claim 1, further comprising generating an action plan for utilizing the ATE based on the merge OEE data.

5. The method of claim 1, wherein the combining comprises combining the machine OEE data and the operator OEE data using a rule-based algorithm.

6. The method of claim 5, wherein the rule based algorithm is implemented in a look-up table routine in an application program.

7. The method of claim 5, wherein the rule based algorithm is implemented in a state machine as a sequence of coded logic functions.

8. The method of claim 1, comprising controlling the ATE with a test application program configured to direct a position of a device under test to a probing station configured to transmit parametric stimuli signals and functional inputs signals to the device under test.

9. The method of claim 1, in which the machine OEE data is generated by a monitor application program that is configured to receive data defining the machine generated event states of the ATE as well as test data generated in response to instructions of the test program.

10. The method of claim 1, wherein the machine generated operational event states of the ATE include one or more of the following: an UP event states, a DOWN event state indicating the ATE is not operational, and an IDLE event state indicating the ATE is operational but waiting for some action.

11. The method of claim 1, wherein the combining comprises selecting the machine OEE data as the merge OEE data in a merged time interval when the machine OEE data indicates the ATE is in the UP event state.

12. The method of claim 1, wherein the combining comprises selecting Unknown state as the merge OEE data when the machine OEE data indicates the DOWN event state and the operator OEE data indicates an UP event state.

13. The method of claim 1, wherein the combining comprises selecting the operator OEE data as the merge OEE data when the machine OEE data indicates the DOWN event state and the operator OEE data indicates any machine event state other than the UP event state.

14. The method of claim 12, wherein the combining comprises selecting a WAIT event state when machine OEE data indicates an IDLE event state.

15. A physical computer-readable storage medium embedded with instructions that operate in a computer environment to:
access machine OEE data including machine generated operational event states of an ATE and real times the machine generated operational event states;
receive operator OEE data including operator data defining operator entered operational event states of the ATE and real times the operator observed operational event states; and
use a rule based algorithm to combine the machine OEE data and the operator OEE data to generate merge OEE data, wherein the merge OEE data provides detail of operational event states of the ATE not available separately in the machine OEE data or the operator OEE data.

16. The storage medium of claim 15, including instructions that calculate an OEE of the ATE based on the merge OEE data.

17. The storage medium of claim 15 in which the merge OEE data includes an IDLE event state indicating the ATE is operational but waiting for some action.

18. The storage medium of claim 15 further including instructions that operate to generate one or more action plans for utilizing the ATE based on the merge OEE data.

19. The storage medium embedded of claim 15, in which the rule-based algorithm is implemented in a look-up table instruction routine.

20. The storage medium of claim 15, in which the rule-based algorithm is implemented in a state machine as a sequence of instructions.

21. The storage medium of claim 20, comprising instructions to provide a position of a device under test to a probing station configured to communicate parametric stimuli signals and functional inputs signals to the device under test.

22. The storage medium of claim 15, in which the machine generated operational event states of the ATE include one or more of the following: one or more UP event states indicating the ATE is operational, a DOWN event state indicating the ATE is not operational, and an IDLE event state indicating the ATE is operational but waiting for some action.

23. A physical computer-readable storage medium embedded with instructions that operate in a computer environment to:
store a first data stream containing machine generated test data associated with a semiconductor tool;
store a second data stream containing operator generated test data associated with the semiconductor tool; and
generate a third data stream containing an evaluative merging of the first and second data streams.

24. The storage medium of claim 23, wherein the instructions to generate the third data stream comprises instructions to execute a rule-based algorithm on the first data stream and the second data stream.

25. The storage medium of claim 23, comprising instructions for calculating an OEE of the semiconductor tool based on the third data stream.
